(19) United States
(12) Patent Application Publication
(10) Pub. No.: US 2025/0007244 A1
(43) Pub. Date: Jan. 2, 2025

(54) SEMICONDUCTOR COMPONENT

(71) Applicant: TRUMPF Photonic Components GmbH, Ulm (DE)

(72) Inventor: Stephan Gronenborn, Aachen (DE)

(21) Appl. No.: 18/884,160

(22) Filed: Sep. 13, 2024

Related U.S. Application Data
(63) Continuation of application No. PCT/EP2023/055403, filed on Mar. 3, 2023.

(30) Foreign Application Priority Data
Mar. 16, 2022 (DE) 10 2022 106 139.6

(51) Int. Cl. H01S 5/183

(52) U.S. Cl. CPC H01S 5/18369

(57) ABSTRACT

A semiconductor component for emitting light includes a main element having an emission region extending on a surface of the main element for emitting the light. A first mirror layer, a second mirror layer, and an active zone extending between the first mirror layer and the second mirror layer substantially parallel to the surface for generating the light are provided in the emission region. The active zone is laterally delimited by a diaphragm such that the active zone has a cross section oriented parallel to the surface that is greater than a cross section of the emission region.

### CROSS REFERENCE TO RELATED APPLICATIONS

This application is a continuation of International Application No. PCT/EP2023/055403 (WO 2023/174717 A1), filed on Mar. 3, 2023, and claims benefit to German Patent Application No. DE 10 2022 106 139.6, filed on Mar. 16, 2022. The aforementioned applications are hereby incorporated by reference herein.

### FIELD

Embodiments of the present invention relate to a semiconductor component for emitting light.

### SUMMARY

Embodiments of the present invention provide a semiconductor component for emitting light. The semiconductor component includes a main element having an emission region extending on a surface of the main element for emitting the light. A first mirror layer, a second mirror layer, and an active zone extending between the first mirror layer and the second mirror layer substantially parallel to the surface for generating the light are provided in the emission region. The active zone is laterally delimited by a diaphragm such that the active zone has a cross section oriented parallel to the surface that is greater than a cross section of the emission region.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a semiconductor component for emitting light with a main element according to some embodiments;

FIG. 2 shows a sectional view through the semiconductor component, schematically showing the intensity distribution and the corresponding mode of the laser light, according to some embodiments;

FIG. 3, FIG. 4, FIG. 5, FIG. 6, FIG. 7, FIG. 8, FIG. 9 and FIG. 10 show different embodiments of the active regions.

### DETAILED DESCRIPTION

Embodiments of the present invention provide a semiconductor component that has a main element with an emission region, extending on a surface of the main element, for the light, to which a first mirror layer, a second mirror layer and an active zone, extending between the two mirror layers substantially parallel to the surface, for generating the light are assigned, which active zone is laterally delimited by a diaphragm such that the active zone has a larger cross section oriented parallel to the surface than the emission region.

The semiconductor component is structured in a stack-like manner, with the light being emitted perpendicular to the surface. Preferably, the semiconductor component can be a VCSEL (vertical-cavity surface-emitting laser).

This provides a semiconductor laser that can produce high light intensity because it has an active zone that is larger than its emission region. This makes it possible to create an array of semiconductor lasers that has a lower fill factor but still produces a light intensity equivalent to a conventional array. However, due to the low fill factor, the realization of arrays with optical elements is easier to accomplish.

Advantageously, the cross section of the emission region may be approximately at most 50%, preferably 25%, but in particular 10%, of the cross section of the active zone. In this case, the active zone delimited by the diaphragm can extend laterally further below the emission region with respect to the optical axis of the emitted light than the emission region.

Preferably, the cross section of the active zone has a dimension of at least 10 micrometers, preferably 20 micrometers, but in particular 40 micrometers, so that different laser modes can be realized within a vertical cavity formed by the mirror layers and the active zone. The dimension may be along a single axis oriented parallel to the main plane of extension of the cross section of the active zone.

In a particular development, the surface in the emission region has a lower reflectivity than the remaining portion of the surface that does not belong to the emission region. This determines the emission region that allows the light to be coupled out.

Furthermore, the reflectivity of the emission region can be <99%, preferably <95%. The remaining portion of the surface may have a reflectivity of at least approximately 99.9%.

In order to achieve the advantageous reflectivity, the first mirror layer is formed adjacent to the surface, wherein a difference in reflectivity between the emission region and the remaining portion of the surface is achieved by a different distance between an outer surface of the first mirror portion and the surface. The distance can be configured such that destructive interference is achieved in the emission region and constructive interference in the remaining portion. This allows a corresponding reflectivity to be produced in a controlled manner.

Preferably, a first mirror layer is formed from a plurality of layers, with some of the layers being removed in the emission region so that the reflectivity in the emission region is reduced. The outermost layers can be removed. A grating can also be introduced into the outermost layers.

Furthermore, a metallic and/or dielectric mirror can be arranged on the remaining portion of the surface that does not belong to the emission region, such that said portion of the surface has a higher reflectivity than the emission region. The mirror layers can remain unchanged so that the reflectivity of the remaining portion is increased by the metallic mirrors.

Preferably, the metallic mirror is arranged on a dielectric layer on the surface. The dielectric layer prevents diffusion and the associated deterioration of the reflectivity generated by the metallic mirror.

To achieve high efficiency, the emission region can be passivated with silicon nitride.

Preferably, the cross section of the active zone is strip-like, so the active zone is strip-like. Strip-like includes both straight strips and curved strips.

Embodiments of the present invention also provide an array of a plurality of semiconductor components, with the cross section of the active zone formed by the diaphragm being strip-like. The cross section can have a longitudinal axis along which the strip-like active zone substantially extends. The longitudinal axis is oriented approximately parallel to the surface.

In particular, the emission region is arranged centrally on the active zone with respect to the cross section. Preferably, the emission region is arranged centrally on the active zone if the cross section of the active zone is a straight strip.

Furthermore, the strip-like active zones can be oriented parallel to each other. The emission regions of the different active zones can be arranged along an imaginary straight line or offset from each other with respect to such a line.

Furthermore, the strip-like active zones can be oriented perpendicular to each other. An active zone with a cross-shaped cross section can also be assigned to an emission region.

The active zones can merge into one another, creating a continuous large active zone. This creates an active zone with a plurality of emission regions. Portions of the large active zone can be oriented at an angle to each other. For example, it is possible to orient the portions at right angles, obtuse angles and/or acute angles to each other.

Furthermore, curved cross sections of the active zone can be assigned to an emission region so that, for example, annular array structures can be formed which have one or more emission regions.

It is to be understood that the features specified above and the features yet to be explained below may be used not only in the specified combination but also in other combinations.

Embodiments of the invention are explained in more detail below with reference to the associated drawings.

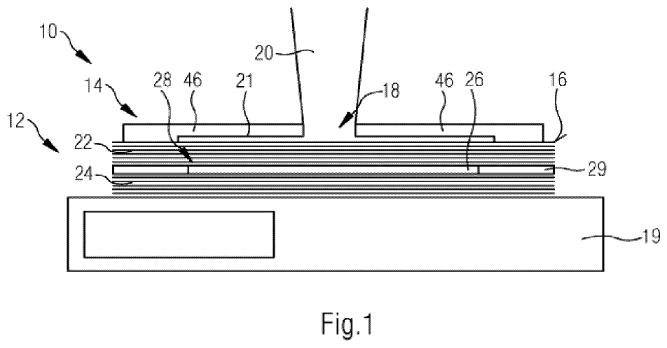

FIG. 1 shows a sectional view of a semiconductor component 10 which has a main element 12 with at least one portion 14 which has an emission region 18 for the light 20 that extends on a surface 16 of the main element 12. Furthermore, the main element 12 comprises a substrate 19 which consists substantially of gallium arsenide.

The portion 14 is arranged on the substrate 19. Electrical contacts 21 are arranged on the surface 16.

A first mirror layer 22, a second mirror layer 24 and an active zone 26, extending between the two mirror layers 22, 24 substantially parallel to the surface 16, for generating the light 20 are arranged in the portion 14.

The mirror layers 22, 24 and the active zone 26 are stacked in a so-called stack structure, to which the laser light 20 is emitted perpendicularly from the surface 16. Such a semiconductor component 10 is referred to as a VCSEL (vertical-cavity surface-emitting laser), the vertical cavity 28 of which is arranged between the mirror layers 22, 24.

The active zone 26 is laterally delimited by a diaphragm 29 with respect to its main plane of extension. The diaphragm 29 extends in the main plane of extension of the active zone 26, which is oriented perpendicular to the propagation direction 30 of the light 20.

The diaphragm 29 limits the active zone 26 to a cross section 32 which corresponds to the opening of the diaphragm 29. The cross section 32 of the active zone 26 is larger than the cross section 34 of the emission region 18. The two cross sections 32, 34 are oriented parallel to each other and spaced from each other in the propagation direction 30 of the light 20.

The cross section 32 of the emission region 18 is approximately at most 50%, preferably 25%, but in particular 10%, of the cross section 34 of the active zone 26. The cross sections 32, 34 are dimensioned according to their zone, which is the result of their dimensions in directions in their respective planes of extension. The basic shape of the cross sections 32, 34 may be similar or identical. For example, the cross sections 32, 34 may have the same dimension in one direction, while they have different dimensions in another direction. Preferably, the cross section 32 of the active zone 26 has a dimension of at least 10 micrometers, preferably 20 micrometers, but in particular 40 micrometers.

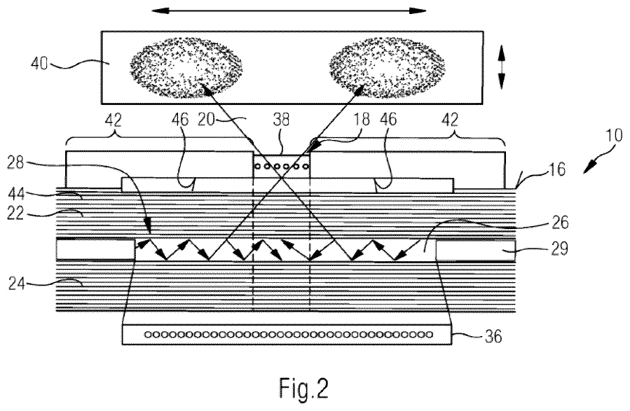

FIG. 2 shows a sectional view of the semiconductor component 10. The active zone 26 which is larger than conventional VCSELs and creates an extended vertical cavity 28 in the plane of extension of the active zone 26. As a result, different laser modes 36 can be formed within the vertical cavity 28, which are schematically shown by zigzag-like arrows in the sectional view of the semiconductor component 10. Purely by way of example, the intensity maxima of a higher-order laser mode 36 are shown below the sectional view of the semiconductor component 10.

The intensity profile of the coupled-out light 20 in the near field 38 in the emission region 18 will have several intensity maxima, while in the far field 40 these intensity maxima combine to form fewer intensity maxima. Purely by way of example, two intensity maxima can arise in the far field 40.

In order to enable the laser light 20 to be coupled out of the emission region 18 which is smaller than the active zone 26, the surface 16 in the emission region 18 has a lower reflectivity than the remaining portion 42 of the surface 16. The remaining portion 42 does not belong to the emission region 18. The active zone 26 is arranged below the remaining portion 42. Preferably, the reflectivity of the emission region is <99%, but preferably <95%. The remaining portion 42, on the other hand, can have a reflectivity of at least approximately 99.9%.

The reflectivity of the surface 16 can be adjusted in particular by measures in the first mirror portion 22 which adjoins the surface. The first mirror portion 22 is designed as a DBR (distributed Bragg reflector) mirror having a plurality of stacked reflection layers 44.

Purely by way of example, a distance between an outer surface of the first mirror layer 22 and the surface 16 in the emission region 18 can be different from the remaining surface. The outer surface of the first mirror layer 22 is arranged on the side facing the surface. By appropriately selecting the different distances, the light 20 will interfere destructively in the emission region and constructively in the region of the remaining surface 16. This results in anti-reflection in the emission region.

Alternatively or additionally, a dielectric layer can be applied to the surface 16, which is designed such that the light 20 interferes destructively in the emission region and interferes constructively in the region of the remaining surface 16.

Furthermore, an anti-reflection coating can additionally be applied to the emission region 18 so that the reflectivity there is reduced.

Alternatively or additionally, at least one of the reflection layers 44 of the first mirror layer 22 in the emission region 18 can be removed. This reduces the reflectivity in the emission region 18. In particular, the outermost reflection layers 44 adjacent to the surface 16 are removed. A grating for polarization and/or diffraction can also be introduced into the outermost reflection layers 44.

Furthermore, alternatively or additionally, a metallic and/or dielectric mirror 46 can be arranged on the remaining portion 42 of the surface 16 which does not belong to the emission region 18. The metallic and/or dielectric mirror 46 can be arranged on a further dielectric layer which is applied to the surface 16 so as to prevent diffusion of the material of the mirror 46. The metallic mirror 46 may contain gold.

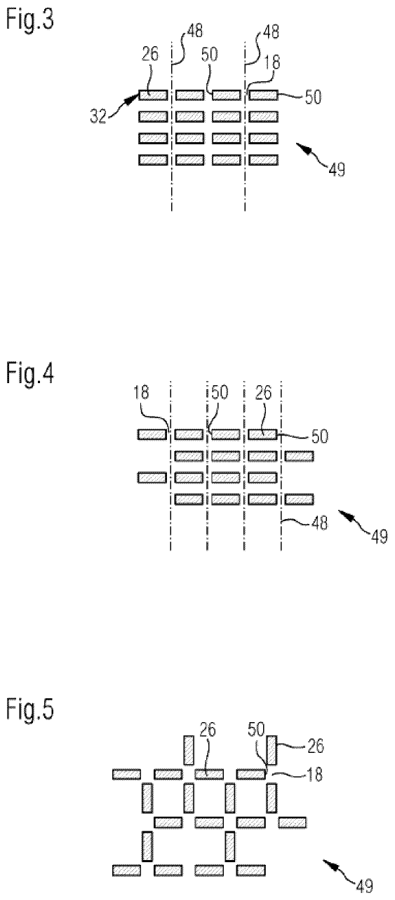

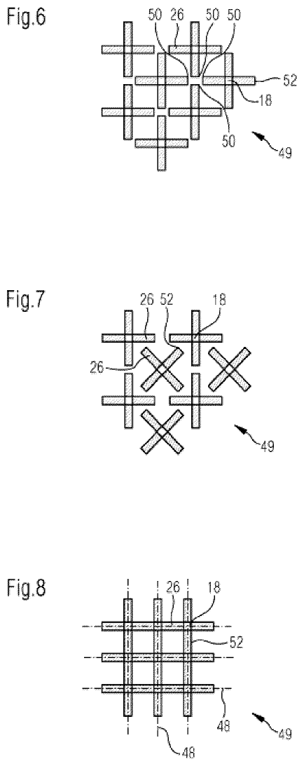

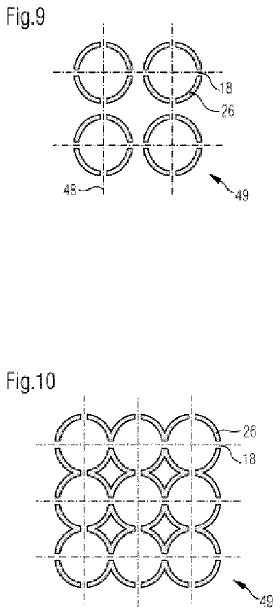

According to FIGS. 3 to 8, the cross section 32 of the active zone 26 is strip-like, which results in a strip-like active zone 26. Strip-like includes both straight strips and curved strips.

In FIGS. 3 and 4, the strip-like cross sections 32 are oriented parallel to each other in an array 49, with the emission region 18 being positioned centrally with respect to the active zone 26. The longitudinal ends 50 of a strip-like active zone 26 are at the same distance from the emission region 18 assigned to it.

According to FIG. 3, the emission regions 18 of the array are lined up along an imaginary straight line 48. Purely by way of example, two rows of four emission regions 18 are shown in FIG. 3. There can be just one row, or rows can be offset from one another with respect to such a line 48.

In FIG. 4, the emission regions 18 are offset from one another, such that emission regions 18 directly adjacent to one another are not arranged on a common imaginary straight line 48. Purely by way of example, the longitudinal ends 50 of a first active zone 26 are arranged on a common line 48 with an emission region 18 of a second active zone 26 directly adjacent to the first zone. This results in the longitudinal ends 50 and the emission regions 18 of different active zones 26 being arranged, in particular alternately, along a common line 48.

In FIG. 5, the strip-like active zones 26 are oriented perpendicular to each other. Each emission region 18 is assigned its own strip-like active zone 26. Preferably, directly adjacent active zones 26 of different emission regions 18 are oriented perpendicular to each other. The longitudinal end 50 of a first active zone 26 is directed towards the emission region 18 of a second active zone 26 adjacent to the first active zone 26.

FIG. 6 shows active zones 26 which have a cross-shaped cross section 32. The cross arms 52 are of equal length and parallel to cross arms 52 of other active zones 26. The longitudinal ends 50 of four adjacent cross-shaped active zones 26 face each other. Between four cross-shaped active zones 26, a cross-shaped active zone 26 is positioned having cross arms 52 which are oriented parallel to the cross arms 52 of the four adjacent cross-shaped active zones 26. The emission regions 18 can be arranged at the intersection points of the cross arms 52.

In FIG. 7, the cross-shaped active zone 26, which is positioned between four adjacent cross-shaped active zones 26, is oriented with respect to the adjacent cross-shaped active zones 26 such that their cross arms 52 are not oriented parallel to each other. The longitudinal ends 50 of the active zone 26 arranged between the four adjacent cross-shaped active zones 26 point to the emission regions 18 of the four adjacent cross-shaped active zones 26.

FIG. 8 shows an array 49 of cross-shaped active zones 26 in which the emission regions 18 are arranged on imaginary lines 48 that run along the cross arms 52. Optionally, the active zones can be directly adjacent to each other or merge into each other, as shown in FIG. 8. Purely by way of example, a continuous active zone 26 can be provided which has a plurality of emission regions 18. Portions of the continuous active zone 26 may be oriented perpendicularly or at another angle to each other. This creates a rectangular grating of active zones 26.

FIG. 9 shows an array 49 of annular active zones 26. Each annular active zone 26 has four emission regions 18 which are spaced approximately 90° apart from each other along the active zone 26. The portions between two emission regions 18 of the annular active zones 26 are approximately 90°. The annular active zones 26 are spaced apart from each other. The emission regions 18 are arranged along intersecting imaginary lines 48. The intersection points of the lines 48 are preferably arranged in the center of an annular active zone 26. The emission regions 18 of directly adjacent annular active zones 26 are located directly opposite one another and are arranged at locations of the active zones 26 which have the smallest distance from one another relative to the remaining portions of the directly adjacent active zones 26.

FIG. 10 shows an array 49 in which the annular active zones 26 are not spaced apart from one another, such that directly adjacent ring-shaped active zones 26 each share an emission region 18. The annular active zones 26 overlap without forming intersection points. The annular active zones 26 overlap in a tangential manner. In each case, an emission region 18 is arranged at the overlap region between the annular active zones 26. Alternatively, the annular active zones 26 can also form intersection points at each of which an emission region 18 is arranged.

One annular active zone 26 has four emission regions 18 which are arranged at intervals of 90° along the annular active zone 26 with respect to its center. As a result, the annular active zones 26 brought together form a coherent network in which the active zones 26 are the meshes.

The features of FIGS. 3 to 8 can be combined with each other. Furthermore, the features of FIGS. 9 and 10 can be combined with each other.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A semiconductor component for emitting light, the semiconductor component comprising:
a main element having an emission region extending on a surface of the main element for emitting the light, wherein a first mirror layer, a second mirror layer, and an active zone extending between the first mirror layer and the second mirror layer substantially parallel to the surface for generating the light are provided in the emission region, wherein the active zone is laterally delimited by a diaphragm such that the active zone has a cross section oriented parallel to the surface that is greater than a cross section of the emission region.

2. The semiconductor component according to claim 1, wherein the cross section of the emission region is at most 50 of the cross section of the active zone.

3. The semiconductor component according to claim 2, wherein the cross section of the emission region is at most 25% of the cross section of the active zone.

4. The semiconductor component according to claim 1, wherein the cross section of the active zone has a dimension of at least 10 micrometers, so that different laser modes is capable of being realized within a vertical cavity formed by the first mirror layer, the second mirror layer, and the active zone.

5. The semiconductor component according to claim 1, wherein a surface in the emission region has a reflectivity that is lower than a reflectivity of a remaining portion of the surface of the main element that does not belong to the emission region.

6. The semiconductor component according to claim 5, wherein the reflectivity of the surface of the emission region is less than 99%.

7. The semiconductor component according to claim 6, wherein the reflectivity of the surface of the emission region is less than 95%.

8. The semiconductor component according to claim 5, wherein a distance between an outer surface of the first mirror layer and the surface in the emission region is different from a distance between the outer surface of the first mirror layer and the remaining portion of the surface of the main element, such that the light interferes destructively in the emission region and interferes constructively in a region of the remaining portion of the surface of the main element.

9. The semiconductor component according to claim 1, wherein an additional dielectric layer is applied to the surface of the main element, wherein the additional dielectric layer is configured such that the light interferes destructively in the emission region and interferes constructively in a region of a remaining portion of the surface of the main element that does not belong to the emission region.

10. The semiconductor component according to claim 5, wherein the first mirror layer is formed from a plurality of layers, wherein some layers of the plurality of layers are removed in the emission region, such that the reflectivity in the emission region is reduced.

11. The semiconductor component according to claim 5, wherein a metallic mirror is arranged on the remaining portion of the surface of the main element that does not belong to the emission region, such that the reflectivity of the remaining portion of the surface is higher than the reflectivity of the emission region.

12. The semiconductor component according to claim 11, wherein the metallic mirror is arranged on a dielectric zone on the surface of the main element.

13. The semiconductor component according to claim 5, wherein a dielectric mirror is arranged on the remaining portion of the surface of the main element that does not belong to the emission region, such that the reflectivity of the remaining portion of the surface is higher than the reflectivity of the emission region.

14. The semiconductor component according to claim 1, wherein the cross section of the active zone is strip-like.

15. An array of a plurality of semiconductor components according to claim 1, wherein the cross section of the active zone formed by the diaphragm is strip-like.

16. The array according to claim 15, wherein the emission region is arranged centrally on the active zone with respect to the cross section of the active zone.

17. The array according to claim 15, wherein the strip-like active zones of the plurality of semiconductor components are oriented parallel to each other.

18. The array according to claim 15, wherein the strip-like active zones of the plurality of semiconductor components are oriented perpendicular to each other.

19. The array according to claim 15, wherein the active zone is assigned a plurality of emission regions, wherein the active zone has portions that are oriented perpendicular to each other.
